(19) United States
(12) Patent Application Publication
(10) Pub. No.: US 2025/0203900 A1
(43) Pub. Date: Jun. 19, 2025

(54) High Electron Mobility Transistor and Method for Manufacturing Same

(71) Applicant: Microchip Technology Incorporated, Chandler, AZ (US)

(72) Inventors: Shesh Mani Pandey, Gilbert, AZ (US); Bomy Chen, Newark, CA (US); Leon Gross, Phoenix, AZ (US); Randy L. Yach, Phoenix, AZ (US)

(73) Assignee: Microchip Technology Incorporated, Chandler, AZ (US)

(21) Appl. No.: 18/915,809

(22) Filed: Oct. 15, 2024

Related U.S. Application Data
(60) Provisional application No. 63/609,420, filed on Dec. 13, 2023.

(51) Int. Cl. H01L 29/66; H01L 29/20; H01L 29/778

(52) U.S. Cl. CPC H10D 30/015; H10D 30/475; H10D 62/8503

(57) ABSTRACT

A High-Electron-Mobility-Transistor that may include a substrate with a buffer layer formed on the substrate. A recess formed in the buffer layer. A barrier layer formed on the buffer layer. A gate recess formed in the barrier layer, the gate recess overlaps the recess in the buffer layer. A drain terminal formed at a first side of the barrier layer. A source terminal formed at a second side of the barrier layer. An isolation structure formed within the gate recess proximate the drain terminal. A doped structure formed adjacent to the isolation structure within the gate recess proximate the source terminal. A gate terminal formed on the doped structure.

### CROSS-REFERENCE TO RELATED APPLICATION

The present application claims priority to U.S. Provisional Patent Application No. 63/609,420, filed on Dec. 13, 2023, the contents of which are hereby incorporated by reference in their entirety.

### TECHNICAL FIELD

The present disclosure relates high electron mobility transistors (HEMTs), and more specifically to high performance HEMTs and methods for manufacturing same to reduce the leakage current of the HEMT.

### SUMMARY

According to an aspect of one or more examples, there is provided a High-Electron-Mobility-Transistor that may include a substrate, a buffer layer formed on the substrate, a recess formed in the buffer layer, a barrier layer formed on the buffer layer, a gate recess formed in the barrier layer, the gate recess overlaps the recess in the buffer layer, a drain terminal formed at a first side of the barrier layer, a source terminal formed at a second side of the barrier layer, an isolation structure formed within the gate recess proximate the drain terminal, a doped structure formed adjacent to the isolation structure within the gate recess proximate the source terminal, and a gate terminal formed on the doped structure. The substrate may comprise bulk gallium nitride, diamond, silicon carbide, sapphire, aluminum nitride, or silicon. The buffer layer may comprise a III-V compound semiconductor. The buffer layer may comprise gallium nitride. The barrier layer may comprise a III-V compound semiconductor, e.g., aluminum gallium nitride. The doped structure may comprise p-doped III-V compound semiconductor such as p-doped gallium nitride. The isolation structure may comprise an insulator having a K value between 1 to 3.9. The isolation structure may comprise polysilicon or silicon dioxide or a mixture of polysilicon and silicon dioxide.

According to an aspect of one or more examples, there is provided a method for producing a High-Electron-Mobility-Transistor. The method may include providing a substrate, forming a buffer layer on the substrate, forming a recess in the buffer layer, forming a barrier layer over the buffer layer, forming a gate recess within the barrier layer, the gate recess overlaps the recess in the buffer layer, forming a drain terminal at a first side of the barrier layer, forming a source terminal at a second side of the barrier layer, forming an isolation structure within the gate recess proximate the drain terminal, forming a doped structure adjacent to the isolation structure within the gate recess proximate the source terminal, and forming a gate terminal onto the doped structure. The substrate may comprise bulk gallium nitride, diamond, silicon carbide, sapphire, aluminum nitride, or silicon. The buffer layer may comprise a III-V compound semiconductor. The buffer layer may comprise gallium nitride. The barrier layer may comprise a III-V compound semiconductor, e.g., aluminum gallium nitride. The doped structure may comprise p-doped III-V compound semiconductor such as p-doped gallium nitride. The isolation structure may comprise an insulator having a K value between 1 to 3.9. The isolation structure may comprise polysilicon or silicon dioxide or a mixture of polysilicon and silicon dioxide.

### BRIEF DESCRIPTION OF DRAWINGS

FIG. 1 is a cross sectional view of a High-Electron-Mobility-Transistor according to one or more examples;

FIG. 2A shows a first step in a method of manufacturing a High-Electron-Mobility-Transistor according to one or more examples;

FIG. 2B shows a second step in a method of manufacturing a High-Electron-Mobility-Transistor according to one or more examples;

FIG. 2C shows a third step in a method of manufacturing a High-Electron-Mobility-Transistor according to one or more examples;

FIG. 2D shows a fourth step in a method of manufacturing a High-Electron-Mobility-Transistor according to one or more examples;

FIG. 2E shows a fifth step in a method of manufacturing a High-Electron-Mobility-Transistor according to one or more examples;

FIG. 2F shows a sixth step in a method of manufacturing a High-Electron-Mobility-Transistor according to one or more examples;

FIG. 2G shows a seventh step in a method of manufacturing a High-Electron-Mobility-Transistor according to one or more examples; and

FIG. 2H shows an eighth step in a method of manufacturing a High-Electron-Mobility-Transistor according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

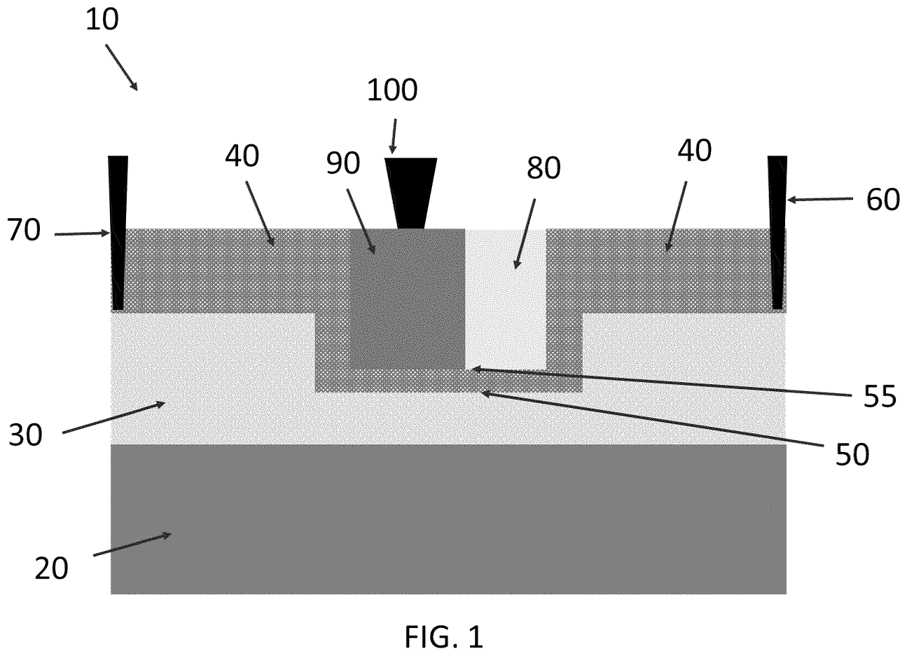

FIG. 1 shows an illustration of a High-Electron-Mobility-Transistor 10 according to one or more examples. The term High-Electron-Mobility Transistor (HEMT), also known as a High-Electron-Mobility Field Effect Transistor (HEM FET), also known as heterostructure FET (HFET) or modulation-doped FET (MODFET), is a field-effect transistor incorporating a junction between two materials with different band gaps (i.e. a heterojunction) at the channel instead of a doped region. As shown in FIG. 1, the High-Electron-Mobility-Transistor 10 has a substrate 20 with a buffer layer 30 formed on the substrate 20. The buffer layer 30 comprises a III-V compound semiconductor such as gallium nitride. The substrate 20 may be bulk gallium nitride, diamond, silicon carbide, sapphire, aluminum nitride, or silicon. A recess 50 is formed in the buffer layer 30. A barrier layer 40 is formed on the buffer layer 30. The barrier layer 40 comprises a III-V compound semiconductor, e.g., aluminum gallium nitride. A gate recess 55 is formed in the barrier layer 40. The gate recess 55 in the barrier layer 40 overlaps, and is contained within, the recess 50 in the buffer layer 30. A drain terminal 60 is formed at a first side of the barrier layer 40. A source terminal 70 is formed at a second side of the barrier layer 40, the second side opposite the first side. An isolation structure 80 is formed within the gate recess 55 proximate the drain terminal 60. A doped structure 90 is formed adjacent to the isolation structure 80 within the gate recess 55 proximate the source terminal 70. A gate terminal 100 is formed on the doped structure 90.

The example High-Electron-Mobility-Transistor 10 of FIG. 1 may include a substrate 20 that may be bulk gallium nitride, diamond, silicon carbide, sapphire, aluminum nitride, or silicon. The buffer layer 30 may comprise any III-V compound semiconductor such as gallium nitride. The barrier layer 40 may comprise any III-V compound semiconductor, e.g., aluminum gallium nitride. The doped structure 90 may comprise a III-V compound semiconductor such as p-doped gallium nitride. The doped structure 90 functions as a gate for the High-Electron-Mobility-Transistor 10. The isolation structure 80 comprises an insulator having a K value between 1 to 3.9 such as polysilicon or silicon dioxide or a mixture of polysilicon and silicon dioxide.

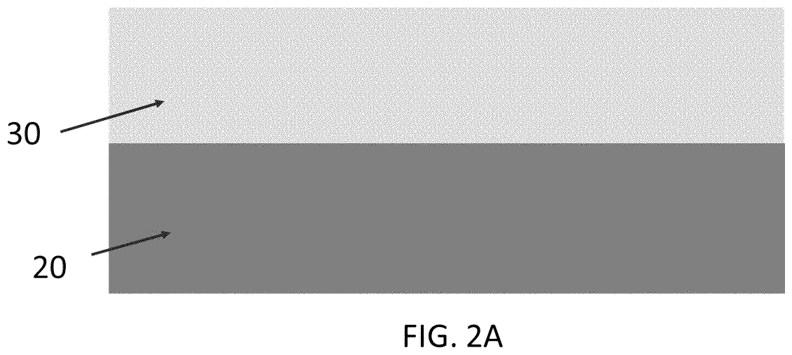

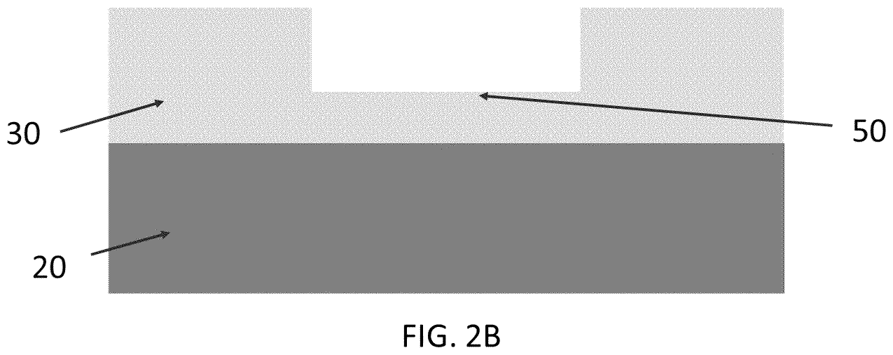

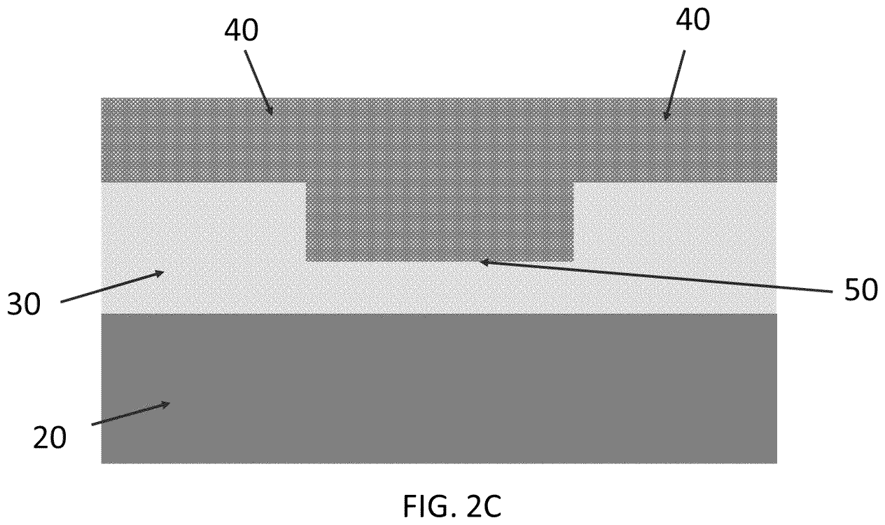

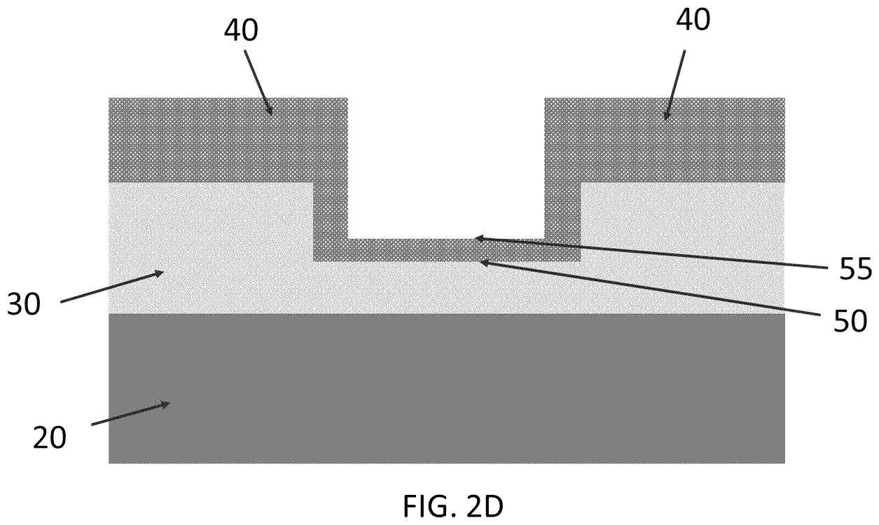

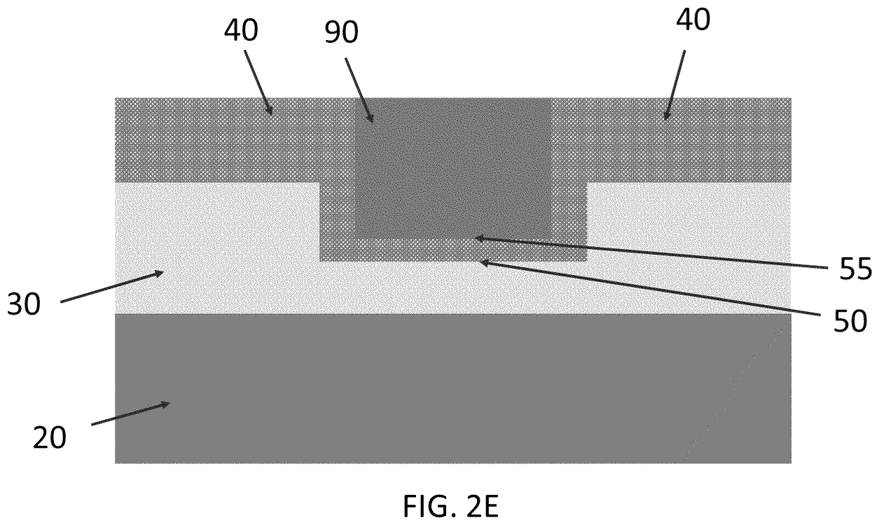

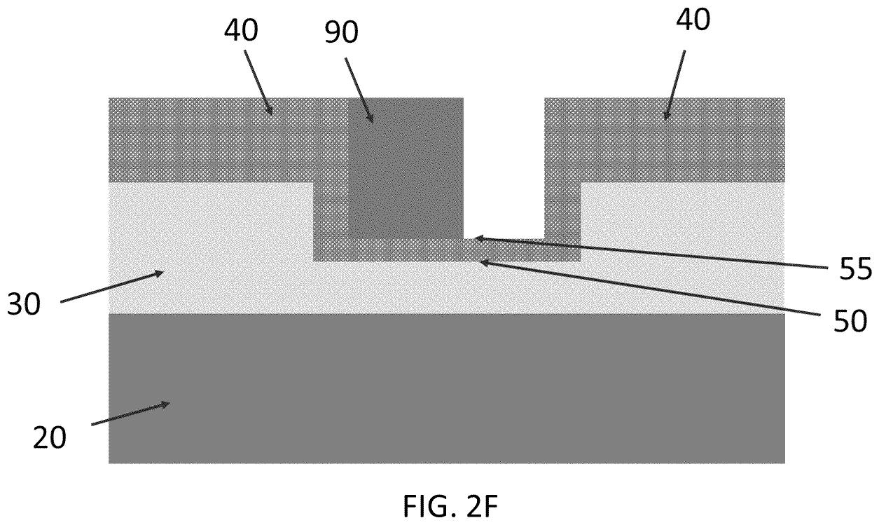

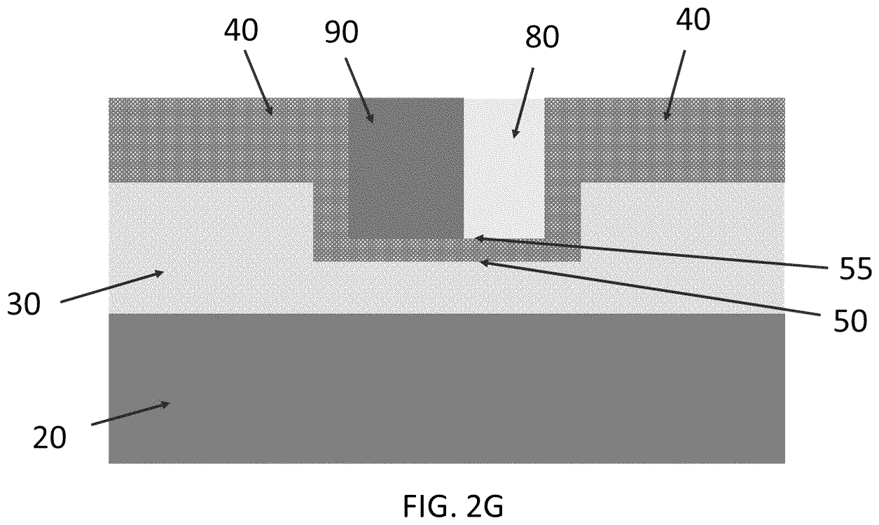

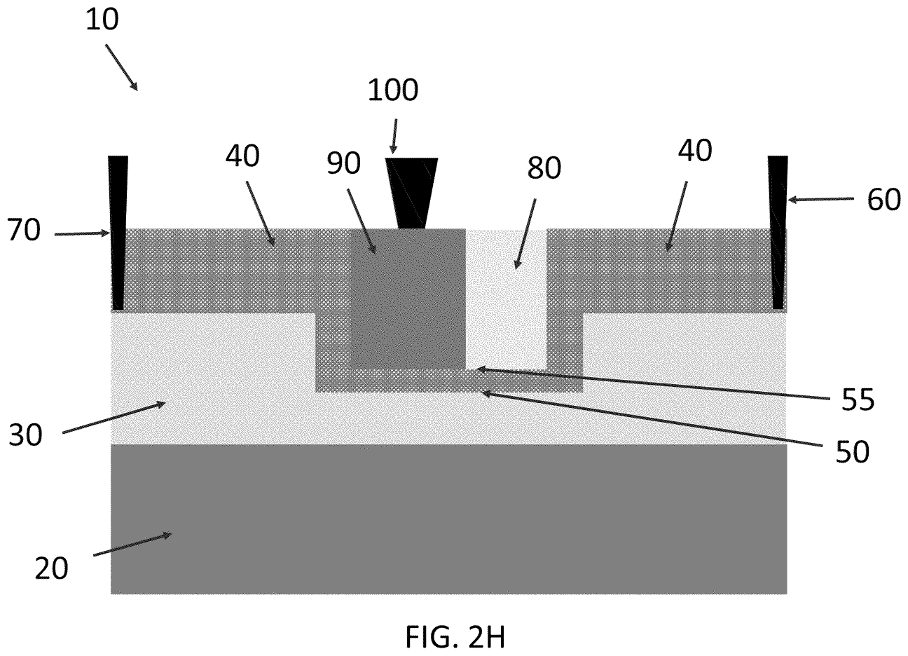

FIGS. 2A-2H show a method of manufacturing a High-Electron-Mobility-Transistor 10 according to one or more examples. Although the example method shown in FIGS. 2A-2H includes steps shown in a particular order, the steps may be performed in a different order, and may include additional steps that are not explicitly shown. In addition, each step presented herein may have multi-steps necessary to carry out the stated step that are not explicitly shown or stated herein.

FIG. 2A shows the first step of the example manufacturing method according to one or more examples. In FIG. 2A, the example method may include forming a buffer layer 30 on a substrate 20. The buffer layer 30 comprises a III-V compound semiconductor such as gallium nitride. The substrate 20 may be bulk gallium nitride, diamond, silicon carbide, sapphire, aluminum nitride, or silicon.

FIG. 2B shows a second step of the example manufacturing method, which includes patterning the buffer layer 30. The patterning of the buffer layer 30 includes the creation of a recess 50 in the buffer layer 30.

FIG. 2C shows a third step of the example manufacturing method, which includes depositing a barrier layer 40 over the patterned buffer layer 30 and into the recess 50. The barrier layer 40 comprises a III-V compound semiconductor, e.g., aluminum gallium nitride.

FIG. 2D shows a fourth step of the example manufacturing method, which includes patterning a gate recess 55 into the barrier layer 40 while leaving a portion of the barrier layer 40 at the bottom of the gate recess 55 and a portion of the barrier layer 40 on the walls of the gate recess 55 of the barrier layer 40. The gate recess 55 in the barrier layer 40 overlaps the recess 50 in the buffer layer 30.

FIG. 2E shows a fifth step of the example manufacturing method, which includes depositing a doped structure 90 into the gate recess 55 and onto the barrier layer 40. The doped structure 90 may comprise p-doped gallium nitride. The p-doped structure 90 functions as a gate for the High-Electron-Mobility-Transistor 10.

FIG. 2F shows a sixth step of the example manufacturing method, which includes patterning the doped structure 90 such that an opening is created adjacent to the remaining doped structure 90 within the gate recess 55 and overlying the barrier layer 40.

FIG. 2G shows a seventh step of the example manufacturing method, which includes depositing an isolation structure 80 into the opening in the gate recess 55 adjacent to the remaining doped structure 90 onto the barrier layer 40. The isolation structure 80 may be an insulator having a K value between 1 to 3.9 such as polysilicon or silicon dioxide or a mixture of polysilicon and silicon dioxide.

FIG. 2H shows an eighth step of the example manufacturing method for a High-Electron-Mobility-Transistor 10, which includes: forming a drain terminal 60 at a first side of the barrier layer 40 that is closest to the isolation structure 80, i.e. the drain terminal 60 is proximate the isolation structure 80; forming a source terminal 70 at a second side of the barrier layer 40 that is closest to the doped structure 90, i.e. the source terminal 70 is proximate the doped structure 90; and forming a gate terminal 100 onto the doped structure 90.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A High-Electron-Mobility-Transistor comprising:
a substrate;
a buffer layer formed on the substrate;
a recess formed in the buffer layer;
a barrier layer formed on the buffer layer;
a gate recess formed in the barrier layer, the gate recess overlaps the recess in the buffer layer;
a drain terminal formed at a first side of the barrier layer;
a source terminal formed at a second side of the barrier layer;
an isolation structure formed within the gate recess proximate the drain terminal;
a doped structure formed adjacent to the isolation structure within the gate recess proximate the source terminal; and
a gate terminal formed on the doped structure.

2. The High-Electron-Mobility-Transistor of claim 1, wherein the substrate comprises bulk gallium nitride, diamond, silicon carbide, sapphire, aluminum nitride, or silicon.

3. The High-Electron-Mobility-Transistor of claim 1, wherein the buffer layer comprises a III-V compound semiconductor.

4. The High-Electron-Mobility-Transistor of claim 3, wherein the barrier layer comprises a III-V compound semiconductor.

5. The High-Electron-Mobility-Transistor of claim 1, wherein the buffer layer comprises gallium nitride.

6. The High-Electron-Mobility-Transistor of claim 5, wherein the barrier layer comprises aluminum gallium nitride.

7. The High-Electron-Mobility-Transistor of claim 1, wherein the doped structure comprises p-doped III-V compound semiconductor.

8. The High-Electron-Mobility-Transistor of claim 1, wherein the doped structure comprises p-doped gallium nitride.

9. The High-Electron-Mobility-Transistor of claim 1, wherein the isolation structure comprises an insulator having a K value between 1 to 3.9.

10. The High-Electron-Mobility-Transistor of claim 1, wherein the isolation structure comprises polysilicon or silicon dioxide or a mixture of polysilicon and silicon dioxide.

11. A method for producing a High-Electron-Mobility-Transistor comprising:
providing a substrate;
forming a buffer layer on the substrate;
forming a recess within the buffer layer;
forming a barrier layer over the buffer layer;
forming a gate recess within the barrier layer, the gate recess overlaps the recess in the buffer layer;
forming a drain terminal at a first side of the barrier layer;
forming a source terminal at a second side of the barrier layer;
forming an isolation structure within the gate recess proximate the drain terminal;
forming a doped structure adjacent to the isolation structure within the gate recess proximate the source terminal; and
forming a gate terminal onto the doped structure.

12. The method for producing a High-Electron-Mobility-Transistor of claim 11, wherein the substrate comprises bulk gallium nitride, diamond, silicon carbide, sapphire, aluminum nitride, or silicon.

13. The method for producing a High-Electron-Mobility-Transistor of claim 11, wherein the buffer layer comprises a III-V compound semiconductor.

14. The method for producing a High-Electron-Mobility-Transistor of claim 13, wherein the barrier layer comprises a III-V compound semiconductor.

15. The method for producing a High-Electron-Mobility-Transistor of claim 11, wherein the buffer layer comprises gallium nitride.

16. The method for producing a High-Electron-Mobility-Transistor of claim 15, wherein the barrier layer comprises aluminum gallium nitride.

17. The method for producing a High-Electron-Mobility-Transistor of claim 11, wherein the doped structure comprises p-doped III-V compound semiconductor.

18. The method for producing a High-Electron-Mobility-Transistor of claim 11, wherein the doped structure comprises p-doped gallium nitride.

19. The method for producing a High-Electron-Mobility-Transistor of claim 11, wherein the isolation structure comprises an insulator having a K value between 1 to 3.9.

20. The method for producing a High-Electron-Mobility-Transistor of claim 11, wherein the isolation structure comprises polysilicon or silicon dioxide or a mixture of polysilicon and silicon dioxide.
